(19) United States
(12) Patent Application Publication
(10) Pub. No.: US 2026/0018548 A1
(43) Pub. Date: Jan. 15, 2026

(54) CONDUCTIVE STRUCTURE WITH MULTIPLE SUPPORT PILLARS

(71) Applicant: QUALCOMM Incorporated, San Diego, CA (US)

(72) Inventors: Yujen CHEN, Taichung City (TW); Aniket PATIL, San Diego, CA (US); Yangyang SUN, San Diego, CA (US)

(21) Appl. No.: 18/767,609

(22) Filed: Jul. 9, 2024

(51) Int. Cl. H01L 23/00

(52) U.S. Cl. CPC H01L 24/13; H01L 24/04; H01L 24/05; H01L 24/11; H01L 24/16; H01L 24/32; H01L 24/73; H01L 2224/0401; H01L 2224/05124; H01L 2224/119; H01L 2224/13018; H01L 2224/13083; H01L 2224/13564; H01L 2224/16145; H01L 2224/73204; H01L 2924/1431

(57) ABSTRACT

Various aspects of the present disclosure generally relate to integrated circuit devices, and to a conductive structure with multiple support pillars. A device includes a die including a contact pad. The device also includes a conductive structure. The conductive structure includes multiple support pillars coupled to the die, a bridge coupled to each of the multiple support pillars, and a cap pillar coupled to the bridge opposite the multiple support pillars. The device further includes a solder cap coupled to the cap pillar. The solder cap is electrically connected to the contact pad via the cap pillar, the bridge, and at least one of the multiple support pillars.

### FIELD

Various features relate to conductive structures, such as a conductive structure for solder bump positioning.

### DESCRIPTION OF RELATED ART

State-of-the-art mobile application devices demand a small form factor, low cost, a tight power budget, and high electrical performance. Additionally, a chip package may include multiple chips that are stacked and electrically connected. For example, a chip may include a copper pillar formed on a pad of the chip, and a solder bump formed on the copper pillar to enable the chip to be electrically coupled to another chip. While the chips are coupled together as part of the chip package, the chip may experience chip package interaction (CPI) stress in which a force or stress on the copper pillar can be provided to the pad of the chip, which can result in damage or failure of the copper pillar, the pad, structures under the pad or pillar, or a combination thereof.

### SUMMARY

Various features relate to integrated circuit devices.

One example provides a device that includes a die including a contact pad. The device also includes a conductive structure. The conductive structure includes multiple support pillars coupled to the die, a bridge coupled to each of the multiple support pillars, and a cap pillar coupled to the bridge opposite the multiple support pillars. The device further includes a solder cap coupled to the cap pillar. The solder cap is electrically connected to the contact pad via the cap pillar, the bridge, and at least one of the multiple support pillars.

Another example provides a method of fabrication that includes forming a conductive structure on a die including a contact pad. The conductive structure includes multiple support pillars coupled to the die, a bridge coupled to each of the multiple support pillars, and a cap pillar coupled to the bridge opposite the multiple support pillars. The method further includes forming a solder cap coupled to the cap pillar. The solder cap is electrically connected to the contact pad via the cap pillar, the bridge, and at least one of the multiple support pillars.

Another example provides a device that includes a die including a contact pad. The device also includes a conductive structure. The conductive structure includes multiple support pillars coupled to the die, a bridge coupled to each of the multiple support pillars, and a cap pillar coupled to the bridge opposite the multiple support pillars. The device further includes a substrate that is electrically connected to the die via the cap pillar, the bridge, at least one of the multiple support pillars, and the contact pad.

### BRIEF DESCRIPTION OF THE DRAWINGS

Various features, nature and advantages may become apparent from the detailed description set forth below when taken in conjunction with the drawings in which like reference characters identify correspondingly throughout. It is noted that one or more figures are annotated with X-, Y-, and/or Z-axes to facilitate recognition of the orientation illustrated in each view.

FIG. 1 illustrates a cross-sectional profile view of an exemplary device that includes a conductive structure with multiple support pillars.

FIG. 2 illustrates a top view of the exemplary device that includes a conductive structure with multiple support pillars.

FIG. 3A illustrates a first part of an exemplary sequence for fabricating an exemplary device that includes a conductive structure with multiple support pillars.

FIG. 3B illustrates a second part of an exemplary sequence for fabricating an exemplary device that includes a conductive structure with multiple support pillars.

FIG. 4 illustrates an exemplary sequence for fabricating an exemplary device that includes a conductive structure with multiple support pillars.

FIG. 5 illustrates an exemplary flow diagram of a method of fabrication for a device that includes a conductive structure with multiple support pillars.

FIG. 6 illustrates various electronic devices that may integrate an exemplary conductive structure with multiple support pillars described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures, and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise”, “comprises”, and “comprising” may be used interchangeably with “include”, “includes”, or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

State-of-the-art mobile application devices demand a small form factor, low cost, a tight power budget, and high electrical performance. Mobile package design has evolved to meet these divergent goals for enabling mobile applications that support multimedia enhancements. For example, fan-out (FO) wafer level packaging (WLP) or FO-WLP process technology is a development in packaging technology that is useful for mobile applications. This chip first FO-WLP process technology solution provides flexibility to fan-in and fan-out connections from a die to package balls. In addition, this solution also provides a height reduction of a first level interconnect between the die and the package balls of mobile application devices. These mobile applications, however, are susceptible to power and signal routing issues when multiple dies are arranged within the small form factor.

Stacked die schemes and chiplet architectures are becoming more common as significant power performance area (PPA) yield enhancements are demonstrated for stacked die and chiplet architecture product lines. As used herein, “stacked dies” and/or “stacked ICs” refer to arrangements in which one die (e.g., a first die) is disposed over (including directly over) another die (e.g., a second die). Additionally, a 3D integrated circuit (3D IC) includes a set of stacked and interconnected dies. Generally, a 3D IC architecture can achieve higher performance, increased functionality, lower power consumption, and/or smaller footprint, as compared to providing the same circuitry in a monolithic die or in a two-dimensional (2D) IC structure. In some stacked die schemes, a pad (e.g., an aluminum pad) and a pillar (e.g., a copper pillar) of a die are sized to support a solder bump so that the die can be conductively coupled to a substrate (or another die). Unfortunately, with stacked die schemes, chip package interaction (CPI) stress can be experienced in which a force or stress on the copper pillar (or solder) is provided to the pad of the chip. Such CPI stresses can result in damage or failure of a copper pillar, a pad, one or more layers under the pillar or the pad, or a combination thereof, and possibly result in a die or chip stack failure.

Disclosed embodiments provide a conductive structure with multiple support pillars. At least one support pillar of the multiple support pillars is electrically connected to a contact pad of a die, and a bridge of the conductive structure extends across the multiple support pillars and has a cap pillar coupled thereto. The cap pillar can be coupled to a solder cap to enable the conductive structure (e.g., the die) to be electrically coupled to another device or substrate. The conductive structure can be formed, for example, as a flip-chip pillar structure of the die and used to provide one or more electrical connections between circuitry of the die and another die (or substrate). Thus, the conductive structure is configured to provide a conductive path between a contact pad of the die and a contact of another device (or substrate).

Aspects of the present disclosure are directed to a conductive structure with multiple support pillars. In some aspects, the multiple support pillars are coupled to a die that includes a contact pad and at least one support pillar of the multiple support pillars is electrically coupled to the contact pad. The conductive structure also includes a bridge coupled to the multiple support pillars, and a cap pillar coupled to the bridge opposite the multiple support pillars. The cap pillar is configured to be coupled to a solder cap to enable the die to be electrically coupled to a substrate (or other die) via the conductive structure. The disclosed device having the conductive structure with multiple support pillars is configured to provide distribution of a force, received by a solder cap, to one or more of the multiple support pillars, provide design flexibility to align solder caps with package bump pads/contacts, compensate for DTC bump alignment with the SOC, provide CPI improvements that reduce or eliminate failures associated with the die, or a combination thereof.

In some drawings, multiple instances of a particular type of feature are used. Although these features are physically and/or logically distinct, the same reference number is used for each, and the different instances are distinguished by addition of a letter to the reference number. When the features as a group or a type are referred to herein e.g., when no particular one of the features is being referenced, the reference number is used without a distinguishing letter. However, when one particular feature of multiple features of the same type is referred to herein, the reference number is used with the distinguishing letter. For example, referring to FIG. 2, multiple locations are illustrated and associated with reference numbers 210A and 210B. When referring to a particular one of these locations, such as a location 210A, the distinguishing letter “A” is used. However, when referring to any arbitrary one of these locations or to these locations as a group, the reference number 210 is used without a distinguishing letter.

Exemplary Device/Implementations Including a Conductive Structure with Multiple Support Pillars

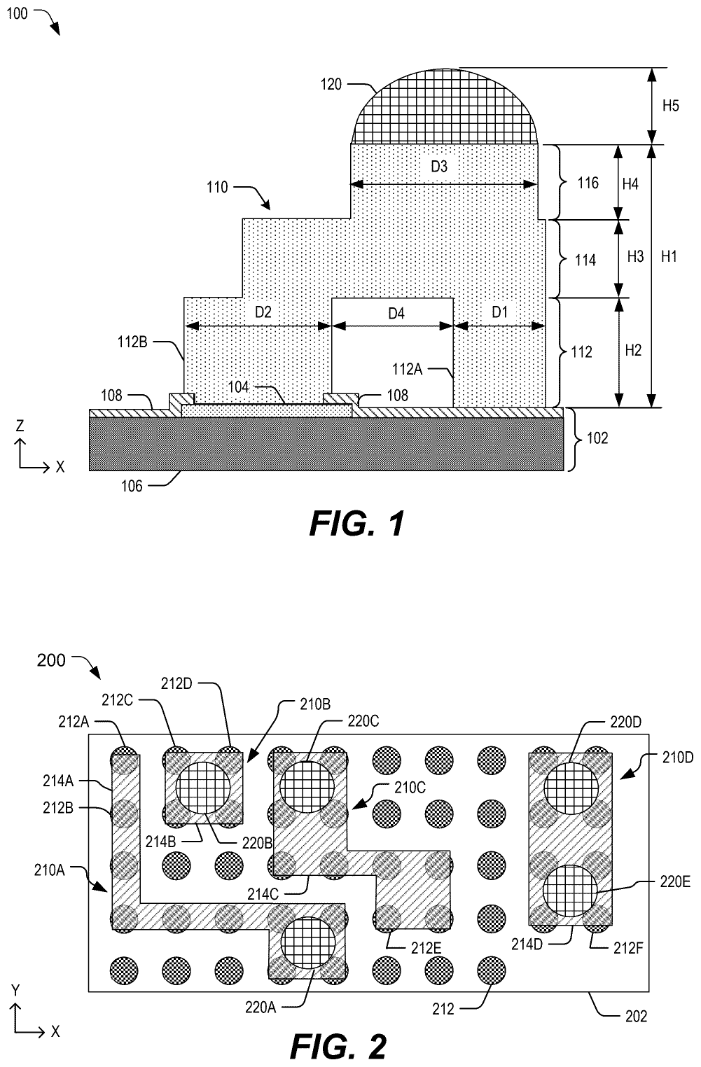

FIG. 1 illustrates a cross-sectional profile view of an exemplary device 100 that includes a conductive structure 110 with multiple support pillars 112. The device 100 also includes a die 102 and a solder cap 120.

The die 102 includes a contact pad 104, a substrate 106, a passivation layer 108. In some implementations, the contact pad 104 is an aluminum contact pad. Although the die 102 is depicted as including a single contact pad 104, in other implementations, the die 102 includes multiple contact pads, such as multiple contact pads that include the contact pad 104. The passivation layer 108, such as a polyimide (PI) layer, includes a dielectric material.

The die 102, such as the substrate 106, can include integrated circuitry. In some implementations, the substrate 106 can include a printed circuit board (PCB), an interposer, or a package substrate, as illustrative, non-limiting examples. The integrated circuitry can be electrically coupled to one or more contact pads, such as the contact pad 104, by back-end-of-line (BEOL) interconnect layers. For example, the BEOL interconnect layers may refer to the conductive interconnect layers for electrically coupling to front-end-of-line (FEOL) active devices of the integrated circuitry. The integrated circuitry can include a plurality of transistors and/or other circuit elements arranged and interconnected to form logic cells, or memory cells, as illustrative, non-limiting examples. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a FEOL process may be used to fabricate the integrated circuitry in and/or over the semiconductor substrate.

The die 102 may include or correspond to particular IC devices that can be arranged and interconnected as a three-dimensional (3D) IC device. In some implementations, the die 102 includes one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the die 102. Additionally, or alternatively, the die 102 may include or operate as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof.

In some implementations, the IC dies are electrically connected to, or integrated with, respective substrates. For example, the die 102 may be electrically connected (e.g., via one or more contacts or interconnects) to the substrate 106. Any of the conductive interconnects and contacts described herein can include, for example, microbumps, conductive pillars, conductive pads (e.g., for pad to pad bonding), or other similar chiplet-to-chiplet interconnect contacts used for three-dimensional (3D) chiplet stacking.

The conductive structure 110 includes the multiple support pillars 112, a bridge 114, and a cap pillar 116. The conductive structure 110 may include a conductive material, such as copper, as an illustrative, non-limiting example.

The multiple support pillars 112 are coupled to the die 102. The multiple support pillars 112 may include a first support pillar 112A and a second support pillar 112B. As shown, the first support pillar 112A of the multiple support pillars 112 is offset in a lateral direction (e.g., the X direction) with respect to the contact pad 104 such that the first support pillar 112A does not overlap the contact pad 104 in a plan view. An entirety of a bottom of the first support pillar 112A of the multiple support pillars 112 is in contact with the passivation layer 108. In other implementations, the entirety of the bottom of the first support pillar 112A is in contact with an under bump metallization layer (not shown) that is positioned between the passivation layer 108 and the first support pillar 112A.

The second support pillar 112B of the multiple support pillars 112 may be positioned above the contact pad 104 in a vertical direction (e.g., the Z direction) with respect to the contact pad 104 such that the second support pillar 112B at least partially overlaps the contact pad 104 in a plan view. At least a portion of a bottom of the second support pillar 112B is in contact with the contact pad 104. In other implementations, an under bump metallization layer (not shown) is positioned between the contact pad 104 and the second support pillar 112B. In some such implementations, the portion of the bottom of the second support pillar 112B is in contact with the under bump metallization layer.

The multiple support pillars 112 may each have the same or different cross-section shape, such as a lateral cross-section shape. The lateral cross-section shape, when viewed in a plan view, may be circular, oval, or another shape. The first support pillar 112A has a first cross-section distance D1 (e.g., lateral cross-section), that is a minimum transverse distance of the first support pillar 112A. The first cross-section distance D1 may be configured to provide structural support for the conductive structure 110 (e.g., the bridge 114) and/or receive or withstand at least a portion of a chip package interaction (CPI) stress. The second support pillar 112B has a second cross-section distance D2 (e.g., lateral cross-section), that is a minimum transverse distance of the second support pillar 112B. The second cross-section distance D2 may be configured to provide structural support for the conductive structure 110 (e.g., the bridge 114), receive or withstand at least a portion of a CPI stress, and/or have an adequate current capacity based on operation of the die 102. In some implementations, the first cross-section distance D1 and the second cross-section distance D2 are the same, while in other implementations the first cross-section distance D1 and the second cross-section distance D2 are different. A distance D4 is a minimum distance (e.g., a lateral distance) between adjacent/neighboring support pillars of the multiple support pillars 112. The distance D4 may be sized to enable the multiple support pillars 112 to provide structural support for the conductive structure 110 (e.g., the bridge 114) and/or to receive or withstand at least a portion of a chip package interaction (CPI) stress. Additionally, or alternatively, the distance D4 may be based on an underfill flow clearance dimension. In some implementations, the distance D4 may be greater than or equal to 20 microns, less than or equal to 30 microns, or a combination thereof, as illustrative, non-limiting examples.

Although the conductive structure 110 is depicted as having two support pillars, in other implementations, the conductive structure 110 includes more than two support pillars 112. An example of a conductive structure that includes more than two support pillars is described further herein at least with reference to FIG. 2. Additionally, or alternatively, although the conductive structure 110 is depicted as being electrically coupled to a single contact pad (e.g., via a single support pillar), in other implementations, the conductive structure 110 can be electrically coupled to two or more contact pads (of the multiple contact pads), such as via two or more support pillars. For example, the first support pillar 112A may be coupled to a first contact pad (e.g., 104) and the second support pillar 112B may be coupled to a second contact pad (e.g., 104). In some implementations, an array of a plurality of support pillars is coupled to the die 102 and the plurality of support pillars include the multiple support pillars 112. An example of an array of a plurality of support pillars is described further herein at least with reference to FIG. 2.

The bridge 114 is coupled to each of the multiple support pillars 112. The bridge 114 extends in a first lateral direction across a first set of support pillars of the multiple support pillars 112, and extends in a second lateral direction across a second set of support pillars of the multiple support pillars 112. The bridge 114 may be configured (e.g., sized) based on a current capacity needed for the constructure, such as a maximum current capacity. For example, the bridge 114 has a vertical cross-section (in the Z direction) to support a maximum current capacity required for operation of the conductive structure 110. To illustrate, the vertical cross-section of the bridge 114 can correspond to a height of the bridge 114 and a width of the bridge 114.

The cap pillar 116 is coupled to the bridge 114 opposite the multiple support pillars 112, such that the bridge 114 is positioned between the cap pillar 116 and the multiple support pillars 112. The cap pillar 116 may be offset from the contact pad 104 in a lateral direction. As shown in FIG. 1, the cap pillar 116 is offset from the contact pad 104 such that the cap pillar 116 does not overlap with the contact pad 104 in a plan view. However, in other implementations, the cap pillar 116 can be offset from the contact pad 104 such that at least a portion of the cap pillar 116 overlaps with the contact pad 104 in a plan view.

The cap pillar 116 has a third cross-section distance D3 (e.g., lateral cross-section), that is a minimum transverse distance of the cap pillar 116. The third cross-section distance D3 may be configured to provide structural support for the solder cap 120, receive or withstand at least a portion of a CPI stress, and/or have an adequate current capacity based on operation of the die 102. In some implementations, the third cross-section distance D3 is greater than each of the first cross-section distance D1 and the second cross-section distance D2. In other implementations, the third cross-section distance D3 may be greater than or equal to each of the first cross-section distance D1 and the second cross-section distance D2.

Although the conductive structure 110 is depicted as having a single cap pillar 116, in other implementations, the conductive structure 110 includes two or more cap pillars 116 coupled to the bridge 114. For example, the conductive structure 110 can include another cap pillar coupled to the bridge 114 opposite the multiple support pillars 112, such that the bridge 114 is positioned between the other cap pillar and the multiple support pillars 112. An example of a conductive structure that includes two or more cap pillars is described further herein at least with reference to FIG. 2.

The solder cap 120 may include a solder bump. The solder cap 120 is coupled to the cap pillar 116. The solder cap 120 is electrically connected to the contact pad 104 via the cap pillar 116, the bridge 114, and at least one of the multiple support pillars 112. In implementations where the conductive structure includes the cap pillar 116 and another cap pillar coupled to the bridge 114, another solder cap can be coupled to the other cap pillar. The other solder cap is electrically connected to the contact pad 104 via the other cap pillar, the bridge 114, and at least one of the multiple support pillars 112.

As shown in FIG. 1, the solder cap 120 is offset (in the lateral direction) from the contact pad 104 such that the cap pillar 116 does not overlap with the contact pad 104 in a plan view. However, in other implementations, the cap pillar 116 can be offset (in the lateral direction) from the contact pad 104 such that at least a portion of the cap pillar 116 overlaps with the contact pad 104 in a plan view.

The conductive structure 110 can have a height H1. The height H1 of the conductive structure 110 can be determined based on a height H2 of the support pillar 112, a height H3 of the bridge 114, and a height H4 of the cap pillar 116. The solder cap 120 can have a height H5.

In some implementations, the height H2 of the support pillar 112 is greater than or equal to 10 microns, less than or equal to 30 microns, or a combination thereof. In some other implementations, the height H2 of the support pillar 112 is further greater than or equal to 15 microns, less than or equal to 25 microns, or a combination thereof. As an illustrative, non-limiting example, the height H2 of the support pillar 112 can be 20 microns.

In some implementations, the height H3 of the bridge 114 is greater than or equal to 5 microns, less than or equal to 25 microns, or a combination thereof. In some other implementations, the height H3 of the bridge 114 is further greater than or equal to 10 microns, less than or equal to 20 microns, or a combination thereof. As an illustrative, non-limiting example, the height H3 of the bridge 114 can be 15 microns.

In some implementations, the height H4 of the cap pillar 116 is greater than 0. In some other implementation, the height H4 of the cap pillar 116 is greater than or equal to 1 micron, less than or equal to 10 microns, or a combination thereof. In some other implementations, the height H4 of the cap pillar 116 is further greater than or equal to 2 microns, less than or equal to 5 microns, or a combination thereof. As an illustrative, non-limiting example, the height H4 of the cap pillar 116 can be 3 microns.

The solder cap 120 has a height H5. In some implementations, the height H5 of the solder cap 120 is 25 microns.

In some implementations, an interface of the cap pillar 116 and the solder cap 120 has a first area that is greater than a second area of an interface of the at least one of the multiple support pillars 112 and the contact pad 104. Stated differently, an end surface area of the cap pillar 116 that is configured to contact the solder cap 120 may be greater than an end surface area of the second support pillar 112B that is configured to be coupled to the contact pad 104.

In some implementations, the device 100 includes an under bump metallization layer on at least the contact pad 104. For example, the under bump metallization layer can be positioned between the contact pad 104 and the at least one of the multiple support pillars. Additionally, or alternatively, the under bump metallization layer can be positioned between one or more of the multiple support pillars 112 and the passivation layer 108.

It should be understood that the device 100 may include additional components, other components, fewer components, or a combination thereof, to support the functionality described herein. As non-limiting examples, the device 100 may include additional IC devices, additional layers, additional dies, additional packages, additional interconnects, additional structures, other components, different components, or a combination thereof, to support the functionality and technical advantages disclosed herein.

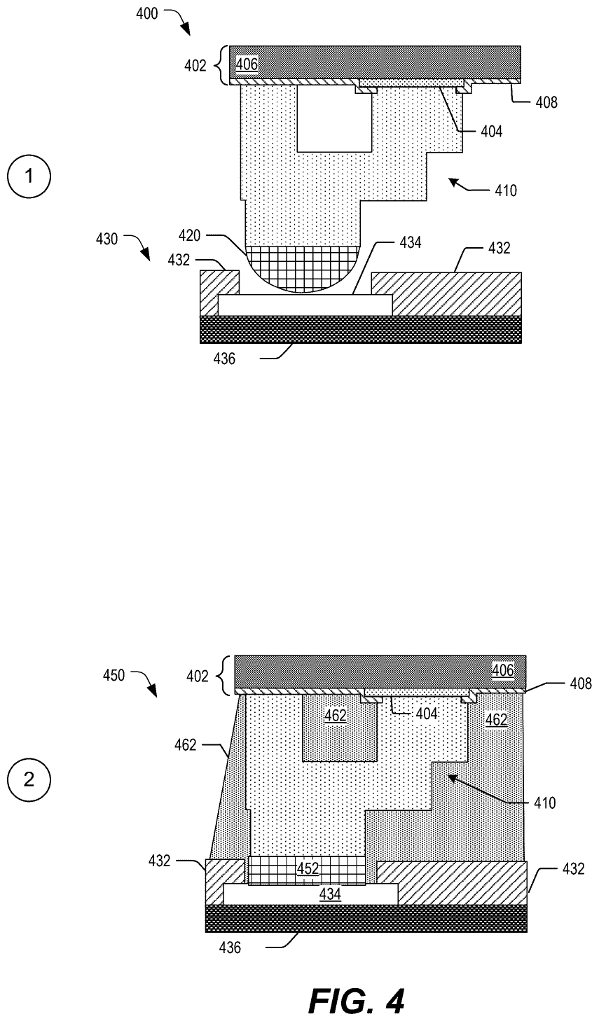

The device 100 may be coupled to (e.g., conductively coupled with) another device (or substrate) via the solder cap 120. To illustrate, the solder cap 120 may be electrically connected to a contact of the other device (or substrate). An example of the device 100 being coupled to another device (or substrate) via the solder cap 120 is described further herein at least with reference to FIG. 4.

The conductive structure 110 is configured to distribute a force received via the cap pillar 116 to two or more of the multiple support pillars 112. For example, the cap pillar 116 is laterally shifted/offset (e.g., in the X direction) with respect to the contact pad 104 such that the cap pillar 116 (and solder cap 120) do not overlap or partially overlap the contact pad 104. To illustrate, the cap pillar 116 may be laterally shifted such that the cap pillar 116 is not entirely or solely above the contact pad 104. Accordingly, when a force (or stress), such as a CPI stress, is provided on the solder cap 120 in a direction toward the die 102, a majority or an entirety the force (or stress) does not go directly to the BEOL of the die 102, such as through the contact pad 104. Rather, the force (or stress) is distributed to the die 102 via multiple support pillars 112 and/or via the underfill material). For example, a portion of the force is distributed, via the first support pillar 112A, to the passivation layer 108, which can be a soft/absorptive material (as compared to the BEOL layer or the contact pad 104) that can absorb the portion of the force and reduce or eliminate damage to the die 102.

The device 100 can be electrically coupled to the other device (or substrate) via the contact pad 104 of the device 100 and a contact of the other device. For example, a conductive path between the contact pad 104 of the device 100 and a contact of the other device may include the solder cap 120, the cap pillar 116, the bridge 114, and at least one of the multiple support pillars 112 (e.g., the second support pillar 112B), and the contact pad 104. In some implementations, the conductive path also includes an under bump metallization layer positioned between the contact pad 104 at a corresponding support pillar 112, such as the second support pillar 112B. It is noted that the conductive structure 110 enables the solder cap 120 to be laterally shifted/offset (e.g., in the X direction) with respect to the contact pad 104 such that the contact pad 104 can be electrically coupled with the contact of the other device (or substrate). In particular, the bridge 114 can be routed to enable the cap pillar 116 (and the solder cap 120) to be laterally shifted/offset (e.g., in the X direction). Stated differently, the bridge 114 may be viewed as a redistribution layer. Accordingly, the conductive structure 110 having the bridge 114 can be designed and formed (without having to redesign the die 102) to enable the die 102 to be electrically coupled to different dies (or substrates) that have different contact placement/locations. Additionally, the conductive structure 110 having the bridge 114 can provide design flexibility and help to align SOC bumps to package bump pads/contacts, to compensate for deep thermal cycles (DTC) bump alignment with the SOC, or a combination thereof.

After the device 100 is conductively coupled to the other device (or substrate), an underfill material may be deposited between the device 100 and the other device (or substrate). In some implementations, the underfill material encapsulates a portion or an entirety of the conductive structure 110. An example of the device 100 after deposition of the underfill material is described further herein at least with reference to FIG. 4.

In some implementations, after the device 100 is conductively coupled to the other device (or substrate), one or more signals may be communicated between the device 100 and the other device (or the substrate). For example, the one or more signals may be communicated via the conductive structure 110 between the contact pad 104 of the device 100 and a contact of the other device (or substrate). To illustrate, the one or more signals can be communicated via the conductive path of the conductive structure 110.

Thus, as compared to other conventional devices that utilize a single pillar structure per solder cap, the device 100 can have a smaller contact pad 104 since the solder cap 120 is supported by the cap pillar 116. For example, the contact pad 104 can be smaller because conductive structure 110 includes multiple support pillars 112 instead of a single pillar, and the solder cap 120 is supported by the cap pillar 116. Additionally, a technical advantage of the conductive structure 110 including the multiple support pillars 112 and/or the bridge 114 is that the die 102 has improved CPI as compared to the conventional single pillar because the multiple support pillars 112 and/or the bridge 114 enable a force on the solder to be distributed to the die 102.

While FIG. 1 illustrates an example device that includes the conductive structure 110 with multiple support pillars 112, in other examples, the device 100 includes one or more additional integrated devices, packages, or some combination thereof that can be present in a stacked integrated circuit without departing from the scope of the subject disclosure. Further, the device 100 of FIG. 1 can be integrated with or included within a wide variety of other devices. For example, the device 100 can be integrated in a smartphone, a tablet computer, a fixed location terminal device, an automobile, a wearable electronic device, a laptop computer, or some combination thereof, as described in more detail below with reference to FIG. 6. As another example, the device 100 that includes one or more of the conductive structures 110 with multiple support pillars 112 disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the conductive structure 110 with multiple support pillars 112 can operate with and/or be electrically coupled to any of these components (or a combination of these components) that includes active circuitry.

In a particular implementation, the device 100 includes the die 102 including the contact pad 104. The device 100 also includes the conductive structure 110. The conductive structure 110 includes multiple support pillars 112 coupled to the die 102, the bridge 114 coupled to each of the multiple support pillars 112, and the cap pillar 116 coupled to the bridge 114 opposite the multiple support pillars 112. The device 100 further includes the solder cap 120 coupled to the cap pillar 116. The solder cap 120 is electrically connected to the contact pad 104 via the cap pillar 116, the bridge 114, and at least one of the multiple support pillars 112.

FIG. 2 illustrates a top view of a particular implementation of a device 200 that includes a conductive structure with multiple support pillars. The device 200 may include or correspond to the device 100 of FIG. 1. For example, the device 200 of FIG. 2 may include one or more of the structures and features as are described above with reference to FIG. 1. Such components and features are physically and operationally the same as described above with reference to FIG. 1. In some implementations, the device 200 includes all of the same features and components as the device 100 of FIG. 1; however, some components and features illustrated in FIG. 1 have been omitted from FIG. 2 for simplicity of illustration. Omission of such features and reference numbers should not be understood as limiting the features and components of FIG. 2 to only those specifically called out below. For example, while FIG. 2 does not show the contact pad 104, the substrate 106, the passivation layer 108 of FIG. 1, or an under bump metallization layer, the device 200 can include the contact pad 104, the substrate 106, the passivation layer 108, or the under bump metallization layer.

In the example shown in FIG. 2, the device 200 includes a die 202. The die 202 may include or correspond to the die 102. The die 202 may include contact pads (e.g., the contact pad 104), a substrate (e.g., the substrate 106), a passivation layer (e.g., the passivation layer 108), or a combination thereof. In some implementations, the die 202 includes multiple contact pads (e.g., the contact pad 104). As shown in FIG. 2, an exposed surface of the die 202 may be an exposed surface of a passivation layer. In some implementations, an under bump metallization layer may be formed on one or more portions of the die 202.

The device 200 includes an array of a plurality of support pillars 212 coupled to the die 202. The plurality of support pillars 212 may include or correspond to the multiple support pillars 112. The plurality of support pillars 212 may be spaced apart and/or sized as described with reference to the support pillars 112 of FIG. 1. The plurality of support pillars 212 include a first support pillar 212A, a second support pillar 212B, a third support pillar 212C, a fourth support pillar 212D, a fifth support pillar 212E, and a sixth support pillar 212F, as representative support pillars. One or more support pillars of the plurality of support pillars 212 may be coupled to a contact pad, coupled to a passivation layer of the die 202, coupled to an under bump metallization layer, or a combination thereof.

The array of the plurality of support pillars 212 is depicted as being arranged in multiple columns (each column extending in the Y direction) and multiple rows (each row extending in the X direction). Each column may include the same number or a different number of support pillars, each row may include the same or a different number of support pillars, or a combination thereof. Although the array of the plurality support pillars 212 is shown as including the multiple columns and the multiple rows, in other implementations, the array may additionally or alternatively include a different configuration or pattern of the support pillars 212. Additionally, or alternatively, the array of the plurality of support pillars 212 may include fewer support pillars, additional support pillars, or the same number of support pillars as shown with reference to the device 200 of FIG. 2.

The device 200 includes multiple conductive structures 210. For example, the multiple conductive structures 210 may include a first conductive structure 210A, a second conductive structure 210B, a third conductive structure 210C, and a fourth conductive structure 210D, as representative conductive structures. The multiple conductive structures 210 may include or correspond to the conductive structure 110. Although the device 200 is depicted as including four conductive structures, in other implementations, the device 200 can include fewer or more than four conductive structures.

Each conductive structure of the multiple conductive structures 210 includes a set of multiple support pillars 212, a bridge 214, and a cap pillar (not shown). The bridge 214 may include or correspond to the bridge 114. It is noted that for each conductive structure 210, the bridge 214 of the conductive structure 210 is shown in FIG. 2 as transparent to show the support pillars 212 of the conductive structure 210. Additionally, or alternatively, the cap pillar may include or correspond to the cap pillar 116. To illustrate, the first conductive structure 210A includes a first set of multiple support pillars 212 (including the first support pillar 212A and the second support pillar 212B), a first bridge 214A, and a first cap pillar. It is noted that the first bridge 214A extends in a first lateral direction (e.g., the Y direction) across a first set of support pillars of the first set of multiple support pillars 212, and extends in a second lateral direction (e.g., the X direction) across a second set of support pillars of the first set of multiple support pillars 212. The second conductive structure 210B includes a second set of multiple support pillars 212 (including the third support pillar 212C and the fourth support pillar 212D), a second bridge 214B, and a second cap pillar. The third conductive structure 210C includes a third set of multiple support pillars 212 (including the fifth support pillar 212E), a third bridge 214C, and a third cap pillar. The fourth conductive structure 210D includes a fourth set of multiple support pillars 212 (including the sixth support pillar 212F), a fourth bridge 214D, and a fourth cap pillar and fifth cap pillar.

For each conductive structure of the multiple conductive structures 210, the conductive structure is electrically coupled to one or more contact pads (e.g., the contact pad 104) of the die 202. For example, one or more support pillars of the first set of multiple support pillars 212 of the first conductive structure 210A is electrically coupled to a respective contact pad (e.g., the contact pad 104). To illustrate, the first support pillar 212A of the first conductive structure 210A is electrically coupled to a contact pad of the die 202. It is noted that the second support pillar 212B of the first conductive structure 210A may not be electrically coupled to and/or positioned on a respective contact pad.

As another example, one or more support pillars of the second set of multiple support pillars 212 of the second conductive structure 210B is electrically coupled to a respective contact pad (e.g., the contact pad 104). Additionally, or alternatively, it is noted that at least one conductive structure 210 may be electrically coupled to two or more contact pads of the multiple contact pads (e.g., the contact pad 104) of the die 202. To illustrate, the third support pillar 212C, the fourth support pillar 212D, or both, may be electrically coupled to a respective contact pad. In some implementations, each support pillar of the second set of multiple support pillars 212 is electrically coupled to a respective contact pad. As another example, one or more support pillars of the third set of multiple support pillars 212 of the third conductive structure 210C is electrically coupled to a respective contact pad (e.g., the contact pad 104). To illustrate, the fifth support pillar 212E of the third conductive structure 210C is electrically coupled to a respective contact pad of the die 202. In some implementations, two or more support pillars of the third set of multiple support pillars 212 are each electrically coupled to a respective contact pad. As another example, one or more support pillars of the fourth set of multiple support pillars 212 of the fourth conductive structure 210D is electrically coupled to a respective contact pad (e.g., the contact pad 104). To illustrate, the sixth support pillar 212F of the fourth conductive structure 210D is electrically coupled to a respective contact pad of the die 202. In some implementations, two or more support pillars of the fourth set of multiple support pillars 212 are each electrically coupled to a respective contact pad—e.g., the fourth conductive structure 201D is electrically coupled to two or more contact pads of multiple contact pads of the die 202. In other implementations, each support pillar of the fourth set of multiple support pillars is electrically coupled to a respective contact pad.

The device 200 may also include solder caps 220. For example, the solder caps 220 include a first solder cap 220A, a second solder cap 220B, a third solder cap 220C, a fourth solder cap 220D, and a fifth solder cap 220E, as representative solder caps. The solder caps 220 may include or correspond to the solder cap 120. Each solder cap 220 may be coupled to a cap pillar. To illustrate, the first solder cap 220A is coupled to the first cap pillar of the first conductive structure 210A, the second solder cap 220B is coupled to the second cap pillar of the second conductive structure 210B, and the third solder cap 220C is coupled to the third cap pillar of the third conductive structure 210C. Additionally, the fourth solder cap 220D is coupled to the fourth cap pillar of the fourth conductive structure 210D, and the fifth solder cap 220E is coupled to the fifth cap pillar of the fourth conductive structure 210D.

For each conductive structure 210, a solder cap 220 of the conductive structure 210 is electrically connected to a contact pad via one or more portions of the conductive structure 210. To illustrate, the first solder cap 220A is electrically coupled to a contact pad (e.g., the contact pad 104) of the die 202 via the first cap pillar, the first bridge 214A, and at least one support pillar (e.g., the first support pillar 212A) of the first set of support pillars 212. The second solder cap 220B is electrically coupled to a contact pad (e.g., the contact pad 104) of the die 202 via the second cap pillar, the second bridge 214B, and at least one support pillar (e.g., the third support pillar 212C) of the second set of support pillars 212. The third solder cap 220C is electrically coupled to a contact pad (e.g., the contact pad 104) of the die 202 via the third cap pillar, the third bridge 214C, and at least one support pillar (e.g., the fifth support pillar 212E) of the third set of support pillars 212. The fourth solder cap 220D is electrically coupled to a contact pad (e.g., the contact pad 104) of the die 202 via the fourth cap pillar, the fourth bridge 214D, and at least one support pillar (e.g., the sixth support pillar 212F) of the fourth set of support pillars 212. Additionally, the fifth solder cap 220E is electrically coupled to a contact pad (e.g., the contact pad 104) of the die 202 via the fifth cap pillar, the fourth bridge 214D, and at least one support pillar (e.g., the sixth support pillar 212F) of the fourth set of support pillars 212.

In some implementations, at least one of the conductive structures 210 is associated with a power distribution network to enable power to be provided between the die 202 and another device (or substrate) electrically coupled to the die 202. In some such implementations, a conductive structure 210 may be considered as an additional power distribution network routing layer for a package. Additionally, or alternatively, a conductive structure 210 can provide greater current capacity for one or more solder caps 220, such as when the conductive structure 210 is electrically coupled to multiple contact pads (e.g., the contact pad 104) of the die, as compared to a conventional single pillar coupled to a contact pad and a solder cap. In some implementations, at least one of the conductive structures 210 may enable multiple contact pads (e.g., the contact pad 104) and/or multiple solder caps 220 to be coupled together. For example, a single conductive structure 210 may enable multiple contact pads (e.g., the contact pad 104) and multiple solder caps 220 to be coupled together. In some implementations, the single conductive structure 210 can also be coupled to ground.

Additionally, or alternatively, the conductive structures 210 may provide one or more benefits as described above with reference to the conductive structure 110 of FIG. 1. For example, the conductive structure 210 may enable the cap pillar (and/or the solder cap 220) to be laterally shifted/offset (e.g., in the X direction and/or the Y direction) with respect to the contact pad such that a force received via the solder cap 220 (or the cap pillar) is distributed to two or more of the multiple support pillars 212 and/or to a passivation layer of the die 202. The ability to redistribute the force may improve a CPI tolerance and reduce contact pad, pillar, and/or die failures. The configuration of the conductive structure 210, and specifically the multiple support pillars 212, may also enable use a smaller contact pad (e.g., the contact pad 104) as compared to a conventional device that includes a single pillar for each solder cap. As another example, the conductive structure 210 may provide design flexibility and help to align SOC bumps (e.g., the solder caps 220) to package bump pads/contacts, to compensate for DTC bump alignment with the SOC (e.g., the die 202), or a combination thereof.

While FIG. 2 illustrates an example device that includes the conductive structure 210 with multiple support pillars 212, in other examples, the device 200 includes one or more additional integrated devices, packages, or some combination thereof that can be present in a stacked integrated circuit without departing from the scope of the subject disclosure. Further, the device 200 of FIG. 2 can be integrated with or included within a wide variety of other devices. For example, the device 200 can be integrated in a smartphone, a tablet computer, a fixed location terminal device, an automobile, a wearable electronic device, a laptop computer, or some combination thereof, as described in more detail below with reference to FIG. 6. As another example, the device 200 that includes one or more of the conductive structures 210 with multiple support pillars 212 disclosed herein can include one or more components, such as a PMIC, an RF device, a passive device, a filter, a capacitor, an inductor, a transmitter, a receiver, or another component. In such devices, the conductive structure 210 with multiple support pillars 212 can operate with and/or be electrically coupled to any of these components (or a combination of these components).

In a particular implementation, the device 200 includes the die 202 including a contact pad. The device 200 also includes the conductive structure 210. The conductive structure 210 includes multiple support pillars 212 coupled to the die 202, the bridge 214 coupled to each of the multiple support pillars 212, and a cap pillar coupled to the bridge 214 opposite the multiple support pillars 212. The device 200 further includes the solder cap 220 coupled to the cap pillar. The solder cap 220 is electrically connected to the contact pad via the cap pillar, the bridge 214, and at least one of the multiple support pillars 212.

Exemplary Sequence(s) for Fabricating a Device/IC Device Including a Conductive Structure with Multiple Support Pillars

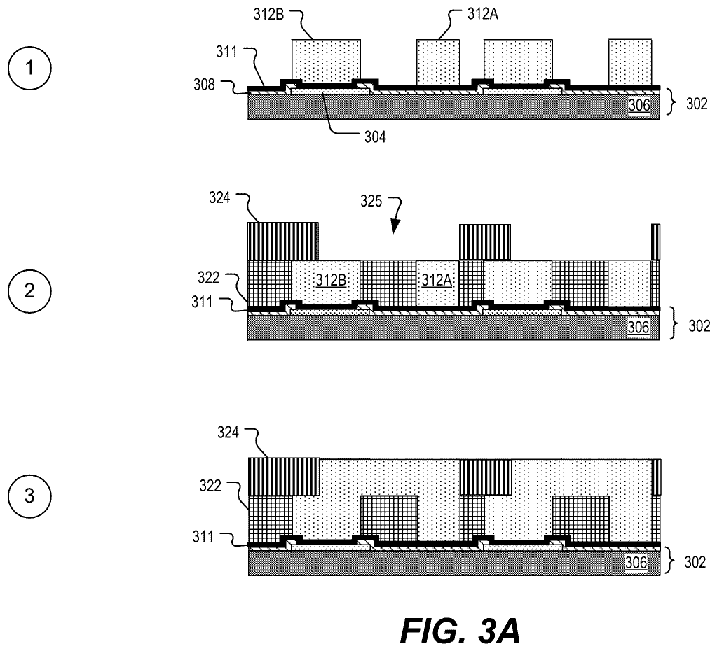

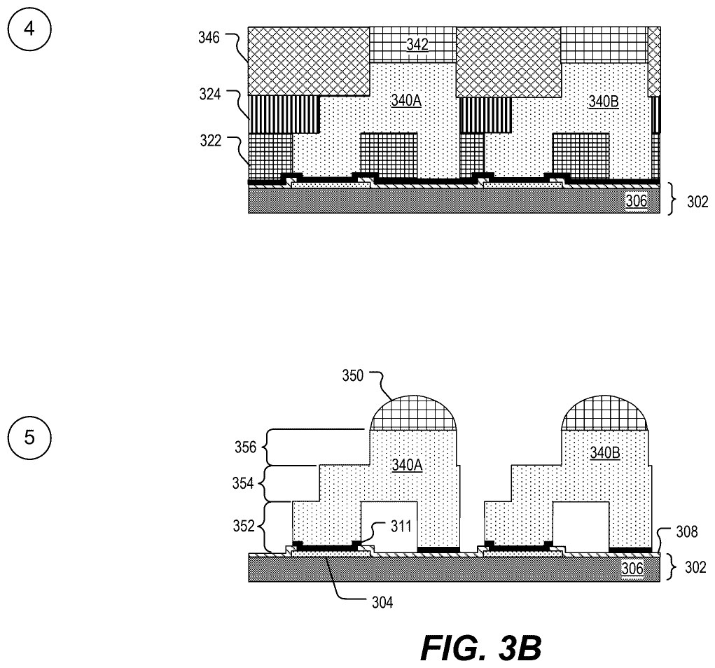

In some implementations, fabricating a device including a conductive structure (e.g., any of the conductive structures 110 or 210) includes several processes. FIGS. 3A-B illustrate an exemplary sequence for fabricating or providing a device that includes a conductive structure with multiple support pillars, as described with reference to any of FIG. 1 or 2. In some implementations, the sequence of FIGS. 3A-B may be used to provide (e.g., during fabrication of) one or more of the device 100 of FIG. 1 or the device 200 of FIG. 2.

It should be noted that the sequence of FIGS. 3A-B may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 3A-B. Each of the various stages of the sequence illustrated in FIGS. 3A-B shows two conductive structures being formed. In other implementations, a single conductive structure may be formed or a plurality of conductive structures (e.g., two or more conductive structures) can be formed concurrently. It is noted that the various stages of FIGS. 3A-B depict a cross-sectional profile view of formation of a device.

Stage 1 of FIG. 3A illustrates a state after formation of a plurality of support pillars 312, such as a representative first support pillar 312A and a representative second support pillar 312B. For example, as part of Stage 1, the plurality of support pillars 312 are formed on a die 302. The plurality of support pillars may include or correspond to the support pillars 112 or 212. In some implementations, the plurality of support pillars 312 are formed as part of an array of support pillars. The die 302 may include or correspond to the die 102 or 202. The die 302 includes a substrate 306 (e.g., a semiconductor layer, such as a portion of a wafer), such as the substrate 106. The plurality of support pillars 312 are formed after formation of multiple contact pads, such as a contact pad 304 on the die 302. Additionally, or alternatively, the plurality of support pillars 312 are formed after formation of a passivation layer 308. Further, the plurality of support pillars 312 are formed after formation of an under bump metallization layer 311. The under bump metallization layer 311 may be formed on the contact pad 304, the passivation layer 308, or a combination thereof.

In some implementations, forming the plurality of support pillars 312 includes depositing and patterning a photo resist layer on the die 302 (e.g., on the contact pad 304, the passivation layer, the under bump metallization layer 311, or a combination thereof). A conductive material, such as copper, can be deposited in the recesses defined within the patterned photo resist layer to form the support pillars 312. As an illustrative, non-limiting example, the conductive material may be deposited using a plating process. After formation of the support pillars 312, a planarization operation or photo resist removal operation may be performed. It is noted that the under bump metallization layer 311 is positioned between the contact pad 304 and the at least one support pillar (e.g., the second support pillar 312B).

Stage 2 illustrates a state after formation of one or more photo resist layers. For example, as part of Stage 2, a first photo resist layer 322, such as a negative photo resist layer, is formed. To illustrate, the first photo resist layer may be formed after formation of the plurality of support pillars 312. In some implementations, a planarization operation is performed after formation of the first photo resist layer 322. Additionally, as part of Stage 2, after formation of the first photo resist layer 322, a second photo resist layer 324, such as a positive photo resist layer, is formed. The second photo resist layer 324 is patterned to form one or more recesses 325 to expose at least a portion of a surface of multiple support pillars of the plurality of support pillars 312. It is noted that with the patterning of the second photo resist layer 324, the recesses 325 may be misaligned with edges of the surfaces of the support pillars 312, such as being misaligned by 0-6 microns, as an illustrative, non-limiting example.

Stage 3 illustrates a state after deposition of a conductive material in the recess 325. For example, the conductive material may include copper. In some implementations, the conductive material deposited into the recess 325 may include or correspond to a bridge, such as the bridge 114 or 214. As an illustrative, non-limiting example, the conductive material may be deposited using a plating process. As part of Stage 3, a planarization operation may be performed on the conductive material.

Stage 4 of FIG. 3B illustrates a state after deposition of a conductive material and deposition of a solder material. For example, as part of Stage 5, a third photo resist layer 346 is formed. The third photo resist layer 346 is patterned to form one or more recesses to expose at least a portion of a surface of the conductive material deposited as part of Stage 3. After formation of the recess in the third photo resist layer 346, a conductive material, such as copper, is deposited in the recess. As an illustrative, non-limiting example, the conductive material may be deposited using a plating process. The conductive material that is deposited may include or correspond to a cap pillar, such as the cap pillar 116 or 216. Formation of the cap pillar may also establish or complete formation of a conductive structure 340, such as the conductive structure 110 or 210. As shown in Stage 4, the conductive structure formed on the die includes a first conductive structure 340A and a second conductive structure 340B.

Additionally, after deposition of the conductive material, as part of Stage 4, a solder material 342 is deposited on the conductive structure 340. For example, the solder material 342 may be deposited on the first conductive structure 340A.

Stage 5 of FIG. 3B illustrates a state after removal of the first photo resist layer 322, the second photo resist layer 324, and the third photo resist layer 346 after a under bump metallization layer etch of the under bump metallization layer 311. Stage 5 also illustrates the state after reflow of the solder material to form a solder cap 350. For example, the solder cap 350 may include or correspond to the solder cap 120 or 220. The solder cap 350 is electrically connected to the contact pad 304 via the conductive structure 340A—e.g., via at least one of the multiple support pillars 352, the bridge 354, and the cap pillar 356. Although the conductive structure 340A is depicted as being coupled to a single contact pad 304, in other implementations, the conductive structure 340A may be electrically coupled to two or more contact pads. Additionally, or alternatively, although the conductive structure 340A is depicted as including a single cap pillar 356 (and electrically coupled to a single solder cap 350), in other implementations, the conductive structure 340A includes two or more cap pillars and is electrically coupled to two or more solder caps.

Formation of the conductive structure 340A including multiple support pillars 312 or 352 is complete after Stage 5 of FIG. 3B. In some implementations, the device of Stage 5 of FIG. 3B can be used to form the device 100 of FIG. 1 or the device 200 of FIG. 2.

FIG. 4 illustrates an exemplary sequence for fabricating or providing a device that includes a conductive structure with multiple support pillars, as described with reference to any of FIG. 1 or 2. In some implementations, the sequence of FIG. 4 may be used to provide (e.g., during fabrication of) one or more of the device 100 of FIGS. 1A-B or the device 200 of FIG. 2.

It should be noted that the sequence of FIG. 4 may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIG. 4. It is noted that the various stages of FIG. 4 depict a cross-sectional profile view of formation of a device.

Stage 1 of FIG. 4 illustrates a state after a first device 400 is positioned to be electrically coupled with a second device 430. The first device 400 includes or corresponds to the device 100 or 200, or the device of Stage 5 of FIG. 3B. The first device 400 includes a die 402. The die 402 may include or correspond to the die 102, 202, or 302. The die 402 includes a contact pad 404, a substrate 406, and a passivation layer 408. The contact pad 404 includes or corresponds to the contact pad 104, 204, or 304. The substrate 406 may include or correspond to the substrate 106 or 306. In some implementations, the substrate 406 can include a printed circuit board (PCB), an interposer, or a package substrate, as illustrative, non-limiting examples. The passivation layer 408 includes or corresponds to the passivation layer 108 or 308. In some implementations, the die 402 includes an under bump metallization layer (not shown), such as the under bump metallization layer 311. The first device 400 also includes a conductive structure 410 and a solder cap 420. The conductive structure 410 includes or corresponds to the conductive structures 110, 210, or 340. The solder cap includes or corresponds to the solder cap 120, 220, or 350.

The second device 430 includes a substrate 436. In some implementations, the substrate 436 can include a die, a PCB, an interposer, or a package substrate, as illustrative, non-limiting examples. The second device 430 also includes a contact pad 434 and a dielectric layer 432 (e.g., a passivation layer).

As part of Stage 1, the first device 400 is positioned with respect to the second device 430 such that the solder cap 420 of the first device 400 is aligned with the contact pad 434 of the second device 430.

Stage 2 illustrates a state after formation of a device 450 that includes a stack of the first device 400 electrically coupled to the second device 430. For example, as part of Stage 2, the solder cap 420 of the first device 400 is electrically coupled with the contact pad 434 of the second device 430. To illustrate, the solder cap 120 may be reflowed to enable solder 452 (e.g., the reflowed solder cap 420) to contact and electrically couple to the contact pad 434 of the second device 430. After the first device 400 is electrically coupled to the second device 430, an underfill material 462 is deposited. For example, the underfill material 462 may be formed such that the underfill material 462 is interposed between the die 402 and the substrate 436. Formation of the device 450 (e.g., a device including the conductive structure 410 with multiple support pillars) is complete after Stage 2 of FIG. 4.

In a particular implementation, the device 450 includes the die 402 including the contact pad 404. The device 450 also includes the conductive structure 410. The conductive structure 410 includes multiple support pillars coupled to the die 302, a bridge coupled to each of the multiple support pillars, and a cap pillar coupled to the bridge opposite the multiple support pillars. The device 450 further includes the solder cap 420 coupled to the cap pillar. The solder cap 420 is electrically connected to contact pad 404) via the cap pillar, the bridge, and at least one of the multiple support pillars.

In another particular implementation, the device 450 includes the die 402 having the contact pad 404. The device 450 also includes the conductive structure 410. The conductive structure 410 includes multiple support pillars coupled to the die, a bridge coupled to each of the multiple support pillars, and a cap pillar coupled to the bridge opposite the multiple support pillars. The device 450 further includes the substrate 436 that is electrically connected to the die 402 via the cap pillar, the bridge, at least one of the multiple support pillars, and the contact pad 404.

In some implementations, the device 450 includes the underfill material 462 interposed between the die 402 and the substrate 436. Additionally, or alternatively, the conductive structure 410 may be associated with a power distribution network to enable power to be provided between the die 402 and the substrate 436. In some such implementations, a conductive structure 410 may be considered as an additional power distribution network routing layer for a package. Additionally, or alternatively, the device 450 includes an under bump metallization layer on the contact pad 404. The under bump metallization layer may include or correspond to the under bump metallization layer 311. The under bump metallization layer can be positioned between the contact pad 404 and the at least one of the multiple support pillars of the conductive structure 410.

Exemplary Flow Diagram of a Method for Fabricating a Device/Integrated Device Including a Conductive Structure with Multiple Support Pillars

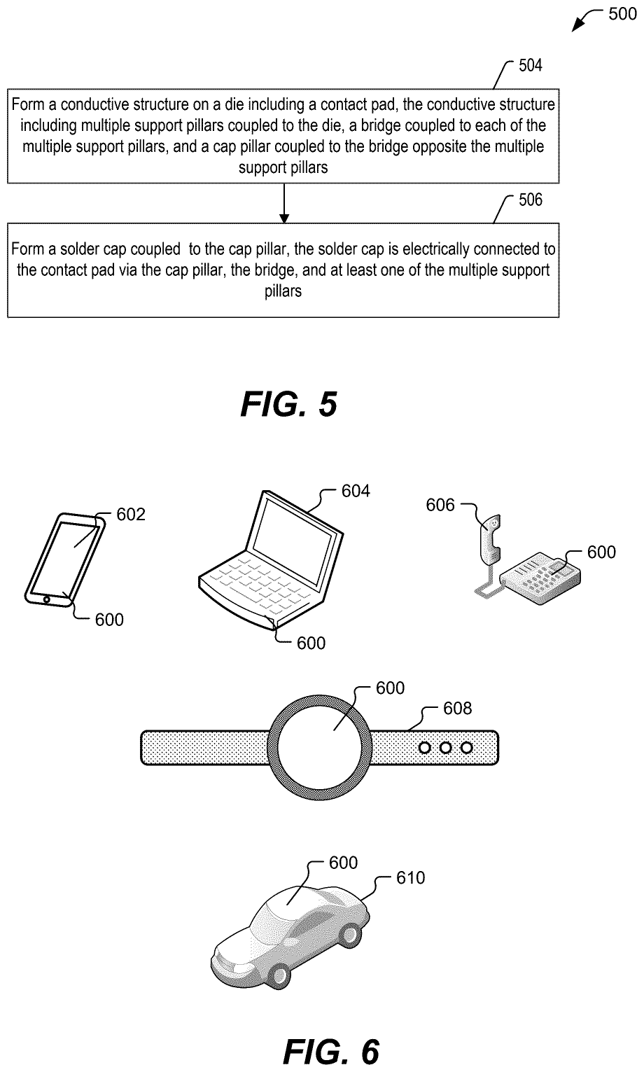

In some implementations, fabricating a device including a conductive structure with multiple support pillars includes several processes. FIG. 5 illustrates an exemplary flow diagram of a method 500 of fabricating an illustrative device that includes a conductive structure with multiple support pillars. In a particular aspect, one or more operations of the method 500 are performed by one or more processors of a fabrication system. In some implementations, operations of the method 500 may be stored as instructions by a non-transitory computer-readable storage medium, and the instructions may be executable by at least one processor to cause the at least one processor to perform operations of the method 500. In some implementations, the method 500 of FIG. 5 may be used to provide or fabricate any of the device 100, 200, 400, or 450, or the device of Stage 5 of FIG. 3B.

It should be noted that the method 500 of FIG. 5 may combine one or more processes in order to simplify and/or clarify the method for providing or fabricating a device that includes a conductive structure with multiple support pillars. In some implementations, the order of the processes may be changed or modified.

At block 504, the method 500 includes forming a conductive structure on a die including a contact pad. For example, Stages 1-4 of FIGS. 3A-B illustrate and describe examples of formation of a conductive structure. The conductive structure of the method 500 can include or correspond to the conductive structure 110, 210, 340, or 410. The die may include or correspond to the die 102, 202, 302, or 402. The contact pad may include or correspond to the contact pad 104, 204, 304, or 404.

The conductive structure includes multiple support pillars coupled to the die, a bridge coupled to each of the multiple support pillars, and a cap pillar coupled to the bridge opposite the multiple support pillars. The multiple support pillars may include or correspond to the support pillars 112, 212, 312, or 352. The bridge may include or correspond to the bridge 114, 214, or 354. The cap pillar may include or correspond to the cap pillar 116 or 356.

In some implementations, forming the conductive structure includes forming the multiple support pillars, forming the bridge, forming the cap pillar, or a combination thereof. For example, Stage 1 of FIG. 3A illustrates and describes examples of formation of the multiple support pillars. In some such implementations, forming the conductive structure includes forming an array of a plurality of support pillars (that include the multiple support pillars of the conductive structure). The array of the plurality of support pillars may include or correspond to the array of the plurality of support pillars described herein at least with reference to FIG. 2. Stages 2 and 3 of FIG. 3A illustrate and describe examples of formation of the bridge. Stage 4 of FIG. 3B illustrates and describes formation of the cap pillar.

In some implementations, the method 500 also includes forming an under bump metallization layer on the contact pad. For example, Stage 1 of FIG. 3A illustrates and describes examples of forming the under bump metallization layer. The under bump metallization layer may include or correspond to the under bump metallization layer 311. The under bump metallization layer may be positioned between the contact pad and the at least one of the multiple support pillars.

At block 506, the method 500 includes forming a solder cap coupled to the cap pillar. For example, Stage 3-4 of FIG. 3B each illustrate and describe examples of forming the solder cap. The solder cap may include or correspond to the solder cap 120, 220, 350, or 420. The solder cap can be electrically connected to the contact pad via the cap pillar, the bridge, and at least one of the multiple support pillars.

In some implementations, the method 500 also includes electrically coupling the die to a substrate via the solder cap. For example, Stage 1 of FIG. 4 illustrates and describes examples of electrically coupling the die to a substrate via the solder cap. For example, the substrate may include or correspond to the substrate 436.

In some implementations, the method 500 also includes forming or depositing an underfill material interposed between the die and the substrate. For example, Stage 2 of FIG. 4 illustrates and describes examples of forming or depositing the underfill material. The underfill material may include or correspond to the underfill material 462.

It is noted that although the method 500 is described as including each of blocks 502, 504, and 506, in other implementations, the method 500 may not include one or more of blocks 502, 504, and 506. For example, the method 500 may include blocks 504 and 506, but not block 502. As another example, the method 500 may include block 504 but not the blocks 502 and 506. Additionally, one or more blocks (or operations) of the method 500 may be combined with one or more operations as described with reference to FIGS. 3A-B.

### Exemplary Electronic Devices

FIG. 6 illustrates various electronic devices that may include or be integrated with any of the device 100 (that includes the conductive structure 110 with multiple support pillars 112), the device 200, the device of Stage 5 of FIG. 3B, the first device 400 of Stage 1 of FIG. 4, or the device 450 of Stage 2 of FIG. 4. For example, a mobile phone device 602, a laptop computer device 604, a fixed location terminal device 606, a wearable device 608, or a vehicle 610 (e.g., an automobile or an aerial device) may include a device 600. The device 600 can include, for example, any of the device 100, the device 200, the device of Stage 5 of FIG. 3B, the first device 400 of Stage 1 of FIG. 4, the device 450 of Stage 2 of FIG. 4, and/or any other integrated device that includes a conductive structure (e.g., 112, 212, 340, or 410) described herein. The devices 602, 604, 606 and 608 and the vehicle 610 illustrated in FIG. 6 are merely exemplary. Other electronic devices may also feature the first device 400 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-7 may be rearranged and/or combined into a single component, process, feature or function, or embodied in several components, processes, or functions. Additional elements, components, processes, and/or functions may also be added without departing from the disclosure. It should also be noted FIGS. 1-7 and its corresponding description in the present disclosure is not limited to dies and/or ICs. In some implementations, FIGS. 1-7 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a portion of a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third”, and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate”, “encapsulating”, or any derivation means that the object may partially encapsulate or completely encapsulate another object.

The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component.

A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements, and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a die including a contact pad; a conductive structure including: multiple support pillars coupled to the die; a bridge coupled to each of the multiple support pillars; and a cap pillar coupled to the bridge opposite the multiple support pillars; and a solder cap coupled to the cap pillar, where the solder cap is electrically connected to the contact pad via the cap pillar, the bridge, and at least one of the multiple support pillars.

Example 2 includes the device of Example 1, where the multiple support pillars of the conductive structure include more than two support pillars.

Example 3 includes the device of Example 1 or Example 2, where the conductive structure includes another cap pillar coupled to the bridge opposite the multiple support pillars; and another solder cap is coupled to the other cap pillar, where the other solder cap is electrically connected to the contact pad via the other cap pillar, the bridge, and the at least one of the multiple support pillars.

Example 4 includes the device of any of Examples 1 to 3, where the bridge extends in a first lateral direction across a first set of support pillars of the multiple support pillars, and extends in a second lateral direction across a second set of support pillars of the multiple support pillars.

Example 5 includes the device of any of Examples 1 to 4, where the solder cap is offset from the contact pad in a lateral direction.

Example 6 includes the device of any of Examples 1 to 4, where the die includes multiple contact pads, the multiple contact pads including the contact pad; and the conductive structure is electrically coupled to two or more contact pads of the multiple contact pads.

Example 7 includes the device of any of Examples 1 to 4, where a minimum distance between neighboring support pillars of the multiple support pillars is based on an underfill flow clearance dimension.

Example 8 includes the device of any of Examples 1 to 4, where a first support pillar of the multiple support pillars is offset in a lateral direction with respect to the contact pad such that the first support pillar does not overlap the contact pad in a plan view.

Example 9 includes the device of any of Examples 1 to 4, where the die includes a passivation layer; and an entirety of a bottom of a first support pillar of the multiple support pillars is in contact with the passivation layer.

Example 10 includes the device of any of Examples 1 to 4, where the conductive structure is configured to distribute a force received via the cap pillar to two or more of the multiple support pillars.

Example 11 includes the device of any of Examples 1 to 4, where an interface of the cap pillar and the solder cap has a first area that is greater than a second area of an interface of the at least one of the multiple support pillars and the contact pad.

According to Example 12, a method of fabrication includes: forming a conductive structure on a die including a contact pad, the conductive structure including: multiple support pillars coupled to the die; a bridge coupled to each of the multiple support pillars; and a cap pillar coupled to the bridge opposite the multiple support pillars; and forming a solder cap coupled to the cap pillar, where the solder cap is electrically connected to the contact pad via the cap pillar, the bridge, and at least one of the multiple support pillars.

Example 13 includes the method of Example 12, where forming the conductive structure includes forming an array of a plurality of support pillars, the plurality of support pillars including the multiple support pillars.

Example 14 includes the method of Example 12 or Example 13, where forming the conductive structure includes forming the bridge.

Example 15 includes the method of any of Examples 12 to 14, where forming the conductive structure includes forming the cap pillar.

Example 16 includes the method of any of Examples 12 to 15, further including forming an under bump metallization layer on the contact pad, the under bump metallization layer is positioned between the contact pad and the at least one of the multiple support pillars.

Example 17 includes the method of any of Examples 12 to 16, further including electrically coupling the die to a substrate via the solder cap.

According to Example 18, a device includes: a die including a contact pad; a conductive structure including: multiple support pillars coupled to the die; a bridge coupled to each of the multiple support pillars; and a cap pillar coupled to the bridge opposite the multiple support pillars; and a substrate, where the substrate is electrically connected to the die via the cap pillar, the bridge, at least one of the multiple support pillars, and the contact pad.

Example 19 includes the device of Example 18, further including an underfill material interposed between the die and the substrate.

Example 20 includes the device of Example 18 or Example 19, where the conductive structure is associated with a power distribution network to enable power to be provided between the die and the substrate.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a die including a contact pad;
a conductive structure including:
multiple support pillars coupled to the die;
a bridge coupled to each of the multiple support pillars; and
a cap pillar coupled to the bridge opposite the multiple support pillars; and
a solder cap coupled to the cap pillar, wherein the solder cap is electrically connected to the contact pad via the cap pillar, the bridge, and at least one of the multiple support pillars.

2. The device of claim 1, wherein the multiple support pillars of the conductive structure include more than two support pillars.

3. The device of claim 1, wherein:
the conductive structure includes another cap pillar coupled to the bridge opposite the multiple support pillars; and
another solder cap is coupled to the other cap pillar, where the other solder cap is electrically connected to the contact pad via the other cap pillar, the bridge, and the at least one of the multiple support pillars.

4. The device of claim 1, wherein the bridge extends in a first lateral direction across a first set of support pillars of the multiple support pillars, and extends in a second lateral direction across a second set of support pillars of the multiple support pillars.

5. The device of claim 1, wherein the solder cap is offset from the contact pad in a lateral direction.

6. The device of claim 1, wherein:
the die includes multiple contact pads, the multiple contact pads including the contact pad; and
the conductive structure is electrically coupled to two or more contact pads of the multiple contact pads.

7. The device of claim 1, wherein a minimum distance between neighboring support pillars of the multiple support pillars is based on an underfill flow clearance dimension.

8. The device of claim 1, wherein a first support pillar of the multiple support pillars is offset in a lateral direction with respect to the contact pad such that the first support pillar does not overlap the contact pad in a plan view.

9. The device of claim 1, wherein:
the die includes a passivation layer; and
an entirety of a bottom of a first support pillar of the multiple support pillars is in contact with the passivation layer.

10. The device of claim 1, wherein the conductive structure is configured to distribute a force received via the cap pillar to two or more of the multiple support pillars.

11. The device of claim 1, wherein an interface of the cap pillar and the solder cap has a first area that is greater than a second area of an interface of the at least one of the multiple support pillars and the contact pad.

12. A method of fabrication, the method comprising:
forming a conductive structure on a die including a contact pad, the conductive structure including:
multiple support pillars coupled to the die;
a bridge coupled to each of the multiple support pillars; and
a cap pillar coupled to the bridge opposite the multiple support pillars; and
forming a solder cap coupled to the cap pillar, wherein the solder cap is electrically connected to the contact pad via the cap pillar, the bridge, and at least one of the multiple support pillars.

13. The method of claim 12, wherein forming the conductive structure includes forming an array of a plurality of support pillars, the plurality of support pillars including the multiple support pillars.

14. The method of claim 12, wherein forming the conductive structure includes forming the bridge.

15. The method of claim 12, wherein forming the conductive structure includes forming the cap pillar.

16. The method of claim 12, further comprising forming an under bump metallization layer on the contact pad, and wherein the under bump metallization layer is positioned between the contact pad and the at least one of the multiple support pillars.

17. The method of claim 12, further comprising electrically coupling the die to a substrate via the solder cap.

18. A device comprising:
a die including a contact pad;
a conductive structure including:
multiple support pillars coupled to the die;
a bridge coupled to each of the multiple support pillars; and
a cap pillar coupled to the bridge opposite the multiple support pillars; and
a substrate, wherein the substrate is electrically connected to the die via the cap pillar, the bridge, at least one of the multiple support pillars, and the contact pad.

19. The device of claim 18, further comprising an underfill material interposed between the die and the substrate.

20. The device of claim 18, wherein the conductive structure is associated with a power distribution network to enable power to be provided between the die and the substrate.
